(19) United States
(12) Patent Application Publication
(10) Pub. No.: US 2008/0145536 A1
(43) Pub. Date: Jun. 19, 2008

(54) METHOD AND APPARATUS FOR LOW TEMPERATURE AND LOW K SiBN DEPOSITION

(75) Inventors: KANGZHAN ZHANG, Santa Clara, CA (US); Sean M. Seutter, San Jose, CA (US); Jacob Grayson, Santa Clara, CA (US); R. Suryanarayanan Iyer, Edina, MN (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/610,424

(22) Filed: Dec. 13, 2006

(51) Int. Cl. C23C 16/00

(52) U.S. Cl. 427/255.38; 118/715

(57) ABSTRACT

A method and apparatus for depositing silicon boron nitride films is provided. The apparatus comprises a chamber, a gas mixing block connected to the chamber, and separate boron-containing precursor, silicon-containing precursor, and nitrogen-containing precursor gas line systems that are connected to the gas mixing block. Methods of depositing a silicon boron nitride film in the apparatus are provided. In another aspect, a method of depositing a silicon boron nitride film includes reacting a boron-containing precursor, silicon-containing precursor, and nitrogen-containing precursor in a chamber, wherein a ratio of the flow rate of the nitrogen-containing precursor into the chamber to the flow rate of the boron-containing precursor is greater than or equal to about 10.

### BACKGROUND OF THE INVENTION

1. Field of the Invention

Embodiments of the present invention generally relate to methods and apparatus for depositing films on semiconductor substrates. More particularly, embodiments of the invention relate to methods and apparatus for depositing silicon boron nitride films.

2. Description of the Related Art

Ultra-large-scale integrated (ULSI) circuits typically include more than one million transistors that are formed on a semiconductor substrate and which cooperate to perform various functions within an electronic device. Such transistors may include complementary metal-oxide-semiconductor (CMOS) field effect transistors.

A CMOS transistor includes a gate structure that is disposed between a source region and a drain region defined in the semiconductor substrate. The gate structure or stack generally comprises a gate electrode formed on a gate dielectric material. The gate electrode controls a flow of charge carriers beneath the gate dielectric in a channel region that is formed between the drain region and the source region so as to turn the transistor on or off. Typically disposed proximate the gate stack is a spacer, which forms a sidewall on both sides thereof. Sidewall spacers serve several functions, including, electrically isolating the gate electrode from source and drain contacts or interconnects, protecting the gate stack from physical degradation during subsequent processing steps, and providing an oxygen and moisture barrier to protect the gate electrode.

A conventional gate stack is formed from materials having dielectric constants of less than about 6 (k<6) and is typically protected by a silicon nitride spacer. Further reduction in transistor sizes will likely require gate layers having dielectric constants of greater than 10 (k>10). If the sidewall spacer is then fabricated from a relatively high k (k>7) material, such as silicon nitride, excessive signal crosstalk between adjacent interconnection lines can occur during use of the device containing the completed gate electrode. While ultra-low k materials (k<3) may be employed as a spacer layer, these materials often lack the necessary structural integrity to survive subsequent processing steps and/or requisite oxygen and moisture imperviousness to protect the gate electrode from corrosion.

In addition, conventional thermal chemical vapor deposition (CVD) process used to prepare silicon nitride spacers requires high deposition temperatures which are typically greater than 650° C. Such silicon nitride spacers deposited at high temperatures have very good conformality. However, the high deposition temperature results in a large thermal budget for the gate device and is not compatible with advanced device manufacturing for 65 nm technology and beyond.

Therefore, there is a need for lower temperature and lower k sidewall spacers for gate stacks.

### SUMMARY OF THE INVENTION

The present invention generally provides methods and apparatus for depositing silicon boron nitride films. In one embodiment, an apparatus for processing a substrate comprises a chamber and a gas delivery system connected to the chamber. The gas delivery system comprises a gas mixing block, a first gas line system having an input connected to a source of a boron-containing precursor and an output connected to a first inlet of the mixing block, a second gas line system having an input connected to a source of nitrogen-containing precursor that does not include silicon and an output connected to a second inlet of the mixing block, and a third gas line system having an Input connected to a source of a silicon-containing precursor and an output connected to a third inlet of the mixing block.

In another embodiment, a method of processing a substrate comprises introducing a substrate into a chamber, introducing a nitrogen-containing precursor that does not include silicon into the chamber at a first flow rate, introducing a boron-containing precursor into the chamber at a second flow rate, wherein the ratio of the first flow rate to the second flow rate is greater than or equal to about 10, introducing a silicon-containing precursor into the chamber, and reacting the nitrogen-containing precursor, the boron-containing precursor, and the silicon-containing precursor in the chamber to deposit a silicon boron nitride film on the substrate. Diborane may be used as the boron-containing precursor. Ammonia may be used as the nitrogen-containing precursor. Bis(tertiary butylamino)silane may be used as the silicon-containing precursor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional view of an embodiment of a chamber that may be used according to embodiments of the invention.

FIG. 2 is a perspective view of a lid assembly and gas delivery system that may be used according to embodiments of the invention.

FIG. 3 is a perspective view of a gas line system for a boron-containing precursor according to an embodiment of the invention.

FIG. 4 is a graph that shows the relationship between the substrate temperature and the deposition rate for the deposition of silicon boron nitride films according to embodiments of the invention.

FIG. 5 is a graph that shows the relationship between the flow rate of the boron-containing precursor and the deposition rate of silicon boron nitride films according to embodiments of the invention.

FIG. 6 is a cross-sectional view of a substrate structure comprising a silicon boron nitride film according to an embodiment of the invention.

### DETAILED DESCRIPTION

The present invention provides methods and apparatus for depositing silicon boron nitride (SiBN) films. The silicon boron nitride films have lower dielectric constants, e.g., between about 4.2 and about 5.7, and low wet etch rates that are desirable for spacer layers.

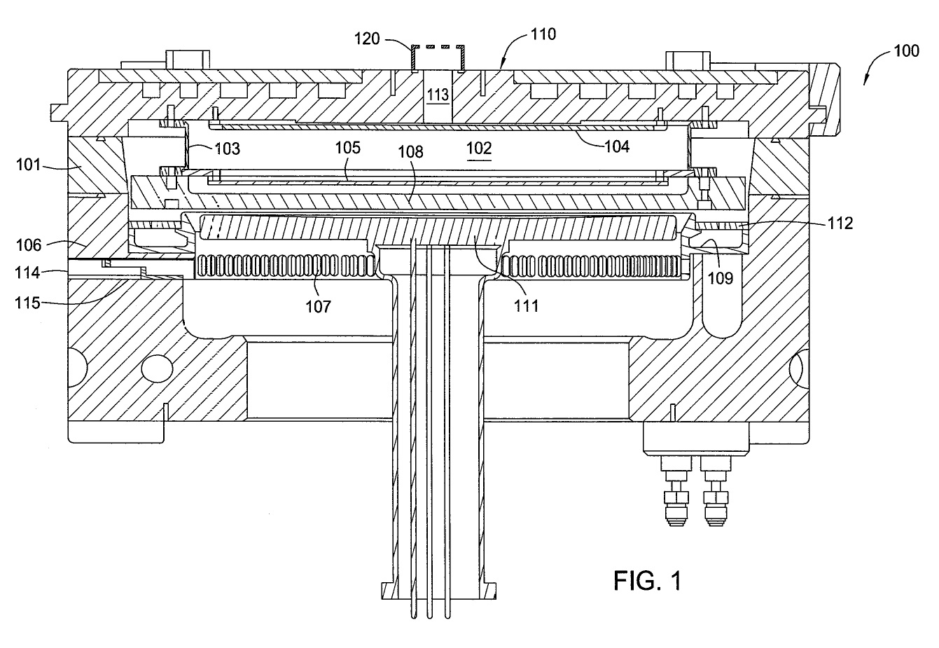

The silicon boron nitride films may be deposited by conventional thermal chemical vapor deposition (CVD) or pulsed CVD. Examples of CVD chambers that may be modified to deposit the silicon boron nitride films include the SiNgen® and SiNgen-Plus™ chambers, both of which are available from Applied Materials, Inc. of Santa Clara, Calif. An exemplary CVD chamber will be described below with respect to FIG. 1. Exemplary CVD chambers are also described in commonly assigned U.S. patent application Ser. No. 10/911,208 (published as U.S. Patent Publication No. 2005/0109276), which was filed on Aug. 4, 2004 and is entitled “Thermal Chemical Vapor Deposition of Silicon Nitride using BTBAS bis(tertiary-butylamino silane) in a single wafer chamber,” in U.S. patent application Ser. No. 11/245,373, which was filed on Oct. 6, 2005 and is entitled “Method and Apparatus for the Low Temperature Deposition of Doped Silicon Nitride,” and in U.S. patent application Ser. No. 11/245,758 (published as U.S. Patent Publication No. 2006/0102076), which was filed on Oct. 7, 2005, and is entitled “Apparatus and Method for the Deposition of Silicon Nitride Films,” which are herein incorporated by reference.

FIG. 1 is a cross sectional view of an embodiment of a single wafer CVD processing chamber 100 having a substantially cylindrical chamber wall 106 closed at the upper end by a chamber lid 110. The chamber lid 110 has a gas mixing block 120 thereon. The gas mixing block 120 is preferably attached directly to the chamber lid, i.e., without any intervening gas lines or other components that separate the gas mixing block from the lid. The chamber lid 110 may further include gas feed inlets, a plasma source, and one or more gas distribution plates described below. Sections of the chamber wall 106 may be heated. A slit valve opening 114 is positioned in the chamber wall 106 for entry of a substrate.

A substrate support 111 supports the substrate and may provide heat to the chamber. In addition to the substrate support, the base of the chamber may contain additional apparatus further described below, including a reflector plate, or other mechanism tailored to facilitate heat transfer, probes to measure chamber conditions, an exhaust assembly, and other equipment to support the substrate and to control the chamber environment.

Feed gas may enter the chamber through a gas delivery system before passing through an inlet 113 in the lid 110 and holes (not shown) in a first blocker plate 104. The feed gas then travels through a mixing region 102 created between a first blocker plate 104 and a second blocker plate 105. The second blocker plate 105 is structurally supported by an adapter ring 103. After the feed gas passes through holes (not shown) in the second blocker plate 105, the feed gas flows through holes (not shown) in a face plate 108 and then enters the main processing region defined by the chamber wall 106, the face plate 108, and the substrate support 111. Exhaust gas then exits the chamber at the base of the chamber through the exhaust pumping plate 107. Optionally, the chamber may include an insert piece 101 between the chamber wall 106 and the lid 110 that is heated to provide heat to the adaptor ring 103 to heat the mixing region 102. Another hardware option illustrated by FIG. 1 is the exhaust plate cover 112, which rests on top of the exhaust pumping plate 109. Finally, an optional slit valve liner 115 may be used to reduce heat loss through the slit valve opening 114.

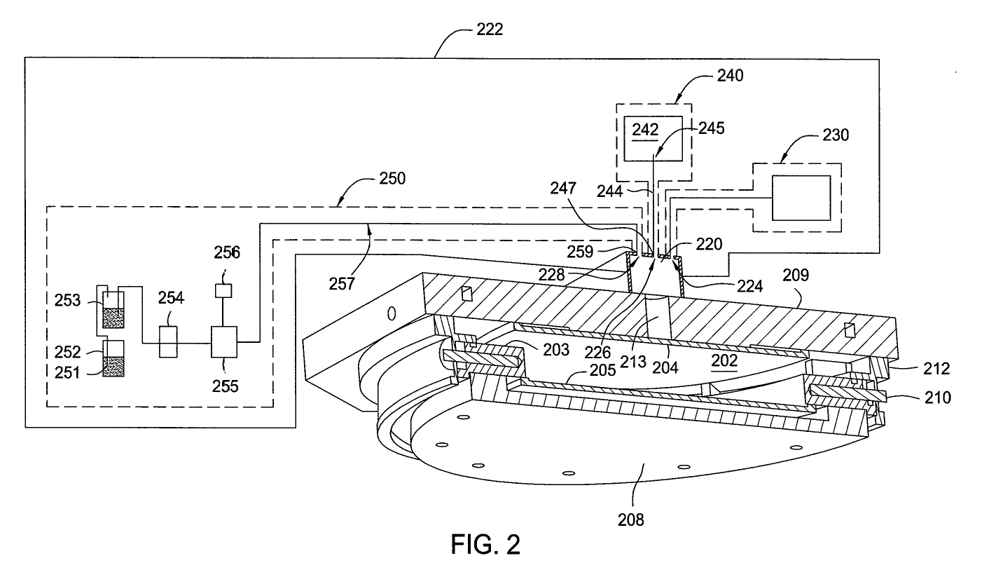

FIG. 2 is an expanded view of an alternative embodiment of a lid assembly. The lid 209 may be separated from the rest of the chamber by thermal insulating break elements 212. The break elements 212 are on the upper and lower surface of heater jacket 203. The heater jacket 203 may also be connected to blocker plate 205 and face plate 208. Optionally, parts of the lid or lid components may be heated.

The lid assembly includes an initial gas inlet 213 through which the feed gas passes before entering a space 202 defined by the lid 209, the thermal break elements 212, the heater jacket 203, and the blocker plates 204 and 205. The space 202 provides increased residence time for the reactant precursor gases to mix before entering the substrate processing portion of the chamber. Heat that may be applied by a heater 210 to the surfaces that define the space 202 helps prevent the buildup of raw materials along the surfaces of the space. The heated surfaces also preheat the reactant precursor gases to facilitate better heat and mass transfer once the gases exit the face plate 208 and enter the substrate processing portion of the chamber.

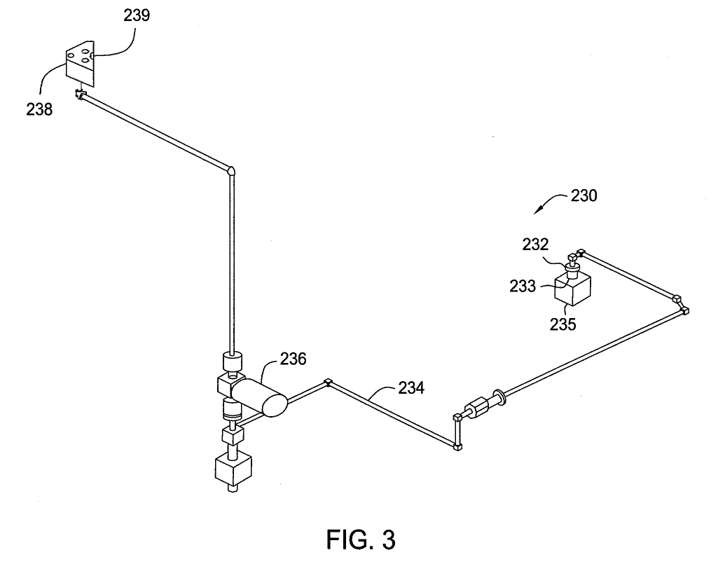

FIG. 2 also shows components of a gas delivery system 222. The gas delivery system 222 includes a gas mixing block 220, which is identical to the gas mixing block 120 described briefly above with respect to FIG. 1. The gas delivery system 222 also includes a first gas line system 230 for delivering a boron-containing precursor to a chamber, a second gas line system 240 for delivering a nitrogen-containing precursor to the chamber, and third gas line system 250 for delivering a silicon-containing precursor to the chamber. The first gas line system 230 is shown schematically in FIG. 2 and in further detail in FIG. 3.

FIG. 3 shows a gas line system 230 that comprises a connector 232 comprising an input 233 to a source 235 of a boron-containing precursor. An example of a boron-containing precursor that may be used is diborane (B₂H₆). A gas line 234 connects the connector 232 to a connection block 238 which comprises an output 239 to a gas mixing block. The output 239 may directly join to an inlet 224 of the gas mixing block 220 (FIG. 2) or it may be joined to the inlet 224 of the gas mixing block 220 by a short line (not shown). Although the gas line 234 is described as one line, the gas line 234 may comprise multiple lines. The gas line system 230 may also include a normal close pneumatic valve 236 in line 234.

Returning to FIG. 2, gas line system 240 connects a source 242 of a nitrogen-containing precursor that does not contain silicon, such as ammonia (NH₃), to the gas mixing block 220 via a gas line 244. The gas line system 240 comprises an input 245 connected to the source 242 of the nitrogen-containing precursor and an output 247 connected to a second inlet 226 of the gas mixing block 220.

Gas line system 250 comprises an input 251 connected to a source 252 of a silicon-containing precursor and an output 259 connected to an inlet 228 of the gas mixing block 220. The silicon-containing precursor may be such as bis(tertiary butylamino)silane (BTBAS), for example. The source 252 of the silicon-containing precursor may be a bulk ampoule. The silicon-containing precursor flows from the source 252 to a process ampoule 253 and then flows into a liquid flow meter 254. The metered silicon-containing precursor flows into a vaporizer 255, such as a piezo-controlled direct liquid injector. Optionally, the silicon-containing precursor may be mixed in the vaporizer 255 with a carrier gas such as nitrogen from a gas source 256 that is connected to the vaporizer 255. Additionally, the carrier gas may be preheated before addition to the vaporizer. The resulting gas is then flowed through gas line 257 and introduced to an inlet 228 of the gas mixing block 220 via output 259. Optionally, the gas line 257 connecting the vaporizer 255 and the gas mixing block 220 may be heated.

By using three separate gas line systems for introducing the silicon-containing precursor, nitrogen-containing precursor, and boron-containing precursor into the gas mixing block, the mixing volume and time during which the precursors are mixed before they are introduced into the processing region of the chamber are minimized. It has been found that using the apparatus described herein to deposit silicon boron nitride films resulted in significantly fewer in-film particles compared to silicon boron nitride films deposited using an apparatus in which the boron-containing precursor and the nitrogen-containing precursor are pre-mixed before they are introduced into a gas mixing block. Also, the generation of equipment contaminating or clogging particles is minimized by not pre-mixing the precursors before they are introduced into the gas mixing block.

Deposition of Silicon Boron Nitride Films

Embodiments of the invention provide a method of depositing a silicon boron nitride film that comprises reacting a nitrogen-containing precursor, a boron-containing precursor, and a silicon-containing precursor to deposit a silicon boron nitride film on a substrate in a chamber. The nitrogen-containing precursor, boron-containing precursor, and silicon-containing precursor may be reacted in a conventional chemical vapor deposition process or a pulsed chemical vapor deposition process.

In one embodiment, a substrate is introduced into an apparatus comprising a chamber, a substrate support disposed in the chamber, a chamber lid, and a gas delivery system connected to the chamber lid, wherein the gas delivery system comprises a gas mixing block, a first gas line system having an input connected to a source of a boron-containing precursor and an output connected to a first inlet of the mixing block, a second gas line system having an input connected to a source of a nitrogen-containing precursor that does not include silicon and output connected to a second inlet of the mixing block, and a third gas line system having an input connected to a source of a silicon-containing precursor and an output connected to a third inlet of the mixing block. A silicon boron nitride film is then deposited on the substrate in the chamber. An example of an apparatus that may be used to perform this embodiment is described above with respect to FIGS. 1-3.

In any of the embodiments of the invention, the boron-containing precursor preferably comprises diborane (B₂H₆), such as pure diborane or diborane mixed with hydrogen, helium, or argon, for example. However, other boron-containing precursors, such as boron trichloride (BCl₃), may be used. A preferred nitrogen-containing precursor that does not contain silicon is ammonia (NH₃). However, other nitrogen-containing precursors that do not contain silicon, such as hydrazine (N₂H₄), may be used. Silicon-containing precursors that may be used include dichlorosilane (SiH₂Cl₂), hexachlorodisilane (Si₂Cl₆), silane (SiH₄), and disilane (Si₂H₆). A preferred silicon-containing precursor, which is also a nitrogen-containing precursor, is bis(tertiary butylamino)silane (BTBAS). Silicon boron nitride films deposited using BTBAS may comprise a small amount of carbon.

Examples of processing conditions that may be used to deposit the silicon boron nitride films will now be provided. The boron-containing precursor, e.g., diborane, may be introduced into a chamber at a flow rate between about 5 sccm and about 50 sccm, such as between about 10 sccm and about 30 sccm. The nitrogen-containing precursor, e.g., NH₃, may be introduced into a chamber at a flow rate between about 50 sccm and about 2000 sccm. The silicon-containing precursor, e.g., BTBAS, may be introduced into a chamber at a flow rate between about 100 mg/min and about 800 mg/min, such as between about 300 mg/min and about 600 mg/min. A carrier or diluent gas such as nitrogen (N₂) may also be introduced into the chamber at a flow rate between about 2000 sccm and about 20000 sccm.

In one embodiment, the flow rates of the nitrogen-containing precursor, e.g., NH₃, and the boron-containing precursor, e.g., diborane, are chosen such that the ratio of the flow rate of the nitrogen-containing precursor to the flow rate of the boron-containing precursor is greater than or equal to about 10. It has been unexpectedly found that using such a ratio for depositing the silicon boron nitride films reduces the number of in-film particle adders having a size of 0.16 μm or greater to about 50 or less.

The substrate temperature during the deposition of the silicon boron nitride films may be between about 300° C. and about 600° C., such as between about 520° C. and about 550° C. The chamber pressure during the deposition of the silicon boron nitride films may be between about 10 Torr and about 500 Torr. The spacing between the substrate support and the faceplate or showerhead may be between about 500 and about 1000 mils, such as between about 500 mils and about 800 mils.

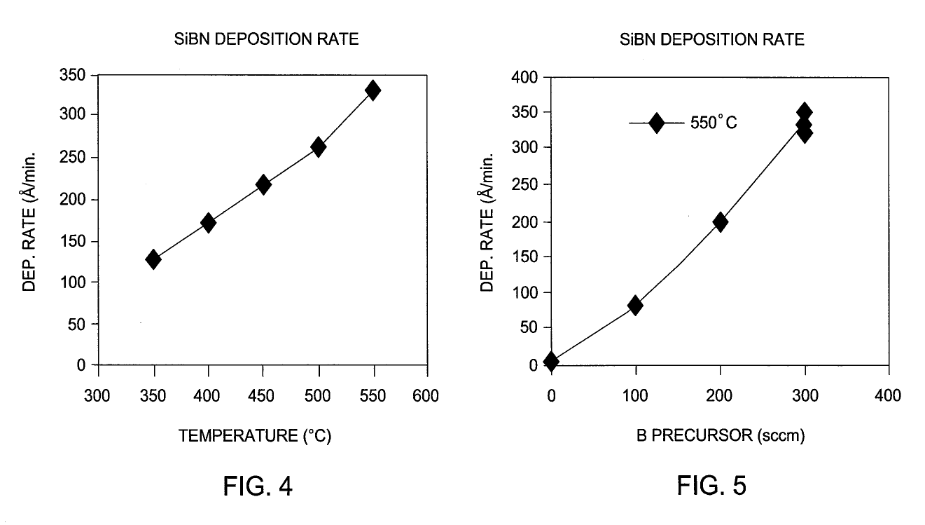

FIG. 4 is a graph that shows tho relationship between the substrate temperature and the deposition rate during the deposition of silicon boron nitride films according to embodiments of the invention. FIG. 5 is a graph that shows the relationship between the flow rate of the boron-containing precursor, i.e., diborane, and the deposition rate of silicon boron nitride films according to embodiments of the invention. FIG. 4 illustrates that deposition rates of greater than about 100 Å/min can be achieved. Thus, embodiments of the invention provide production-worthy methods of depositing silicon boron nitride films. FIG. 5 illustrates that the deposition rate of the silicon boron nitride films may be increased by increasing the flow rate of the boron-containing precursor.

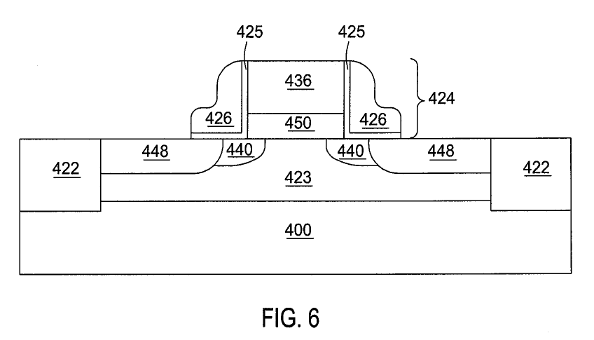

In one aspect, the silicon boron nitride films provided herein may be used as spacer layers in transistor gates. FIG. 6 illustrates a transistor having a gate structure formed according to one embodiment of the invention. A plurality of field isolation regions 422 are formed in a substrate 400. The plurality of field isolation regions 422 isolate a well 423 of one type conductivity (e.g., p-type) from adjacent wells (not shown) of other type conductivity (e.g., n-type). A gate dielectric layer 450 is formed on the well 423. Typically, the gate dielectric layer 450 may be formed by depositing or growing a layer of a material such as silicon oxide (SiOₓ), silicon oxynitride, or a high dielectric constant material (k>10).

Further, an electrically conductive gate electrode layer 436 is blanket deposited over gate dielectric layer 450. Generally, the gate electrode layer 436 may comprise a material such as doped polysilicon, undoped polysilicon, silicon carbide, or silicon-germanium compounds. However, contemplated embodiments may encompass a gate electrode layer 436 containing a metal, metal alloy, metal oxide, single crystalline silicon, amorphous silicon, silicide, or other material well known in the art for forming gate electrodes.

A hard-mask layer (not shown), such as a nitride layer, is deposited via a CVD process over gate electrode layer 436. A photolithography process is then carried out including the steps of masking, exposing, and developing a photoresist layer to form a photoresist mask (not shown). The pattern of the photoresist mask is transferred to the hard-mask layer by etching the hard-mask layer to the top of the gate electrode layer 436, using the photoresist mask to align the etch, thus producing a hard-mask (not shown) over the gate electrode layer 436.

The structure is further modified by removing the photoresist mask and etching the gate electrode layer 436 down to the top of the gate dielectric layer 450, using the hard-mask to align the etch, thus creating a conductive structure including the remaining material of gate electrode layer 436 underneath the hard-mask. This structure results from etching the gate electrode layer 436, but not the hard-mask or gate dielectric layer. Continuing the processing sequence, gate dielectric layer 450 is etched. The gate electrode 436 and the gate dielectric layer 450 together define a composite structure 424, sometimes known as a gate stack, or gate, of an integrated device, such as a transistor.

In further processing of the gate stack, shallow source/drain extensions 440 are formed adjacent source/drain regions 448 by utilizing an implant process. The gate electrode 436 protects the substrate region beneath the gate dielectric from being implanted with ions. A rapid thermal process (RTP) anneal may then be performed to drive the tips 440 partially underneath the gate dielectric.

Next, an optional conformal thin oxide layer 425 is deposited over the entire substrate surface. This oxide layer is used to protect the silicon surface from the spacer layer 426, which is typically a silicon nitride layer. The conformal thin oxide layer is typically deposited in a low pressure chemical vapor deposition chamber at high temperature (>600° C.). The thin oxide layer relaxes the stress between the silicon substrate and the nitride spacer and it also protects the gate corners from the silicon nitride spacer by providing another layer of material.

In one embodiment of the invention, a silicon boron nitride spacer layer 426, with a thickness in the range between about 100 Å to about 800 Å, preferably between about 100 Å to about 500 Å, is blanket deposited over the top of the composite structure 424 and along the entire length of the sides of the gate stack 424, including the entire length of the sidewalls of the gate electrode 436 and the gate dielectric. At the same time, the silicon boron nitride spacer layer 426 is deposited on top of any exposed portion of the substrate 400 or isolation regions 422.

The silicon boron nitride films provided herein have several properties that are desirable properties for spacer layers. The silicon boron nitride films can be deposited at temperatures as low as 350° C. at a good deposition rate. By tuning the flow rates of the precursors, silicon boron nitride films having a dielectric constant (k) between about 4.2 and about 5.7 can be obtained. For example, a dielectric constant of about 4.5 (as measured by a SSM 6200 metrology system, available from Solid State Measurements, Inc., at a frequency of 1 MHz for a capacitor area of 3×10⁻⁵ cm²) was obtained for a silicon boron nitride film deposited at 520° C. and 275 Torr with a diborane flow rate of 30 sccm, an NH₃ flow rate of 40 sccm, a BTBAS flow rate of 305 mgm, and a nitrogen flow rate of about 1300 sccm. Such low dielectric constant spacers improve device performance, e.g., device speed, by reducing the fringe capacitance between the gate electrode and the source and drain regions of a transistor, which is becoming an increasingly important factor as gate lengths reach 45 nm or less.

The silicon boron nitride films provided herein also have good step coverage and pattern loading effect (PLE) performance. The silicon boron nitride films were deposited over densely patterned features (60 nm line width, 180 nm line spacing) semi-densely patterned features (65 nm line width, 435 nm line spacing), and isolated features (65 nm line width, 1185 nm line spacing). The silicon boron nitride films provided greater than 92% step coverage for all three feature densities, and the pattern loading effect was about 10%.

TABLE 1

| | Deposition | Etching | Wet etching | Solution |
|---|---|---|---|---|
| Film | Temperature | Chemistry | rate (Å/min.) | temperature |
| SiBN | 400–550° C. | HF (100:1) | <1 | 20° C. |
| SiBN | 400–550° C. | 49% HF | ~4 | 20° C. |
| SiBN | 400–550° C. | 85% H₃PO₄ | ~1 | 165° C. |
| SiBN | 400–550° C. | 85% H₂SO₄ | 7.6 | 120° C. |

Additionally, as shown by Table 1, the silicon boron nitride films provided herein have low wet etch rates, which is a desirable property for films that are used as spacers or other types of protection layers.

While the foregoing is directed to embodiments of the present invention, other and further embodiments of the invention may be devised without departing from the basic scope thereof, and the scope thereof is determined by the claims that follow.

What is claimed is:

1. An apparatus for processing a substrate, comprising:
a chamber;
a gas delivery system connected to the chamber, wherein the gas delivery system comprises:
a gas mixing block;
a first gas line system having an input connected to a source of a boron-containing precursor and an output connected to a first inlet of the mixing block;
a second gas line system having an input connected to a source of nitrogen-containing precursor that does not include silicon and an output connected to a second inlet of the mixing block; and
a third gas line system having an input connected to a source of a silicon-containing precursor and an output connected to a third inlet of the mixing block.

2. The apparatus of claim 1, wherein the gas mixing block is directly attached to the chamber.

3. The apparatus of claim 1, wherein the boron-containing precursor is diborane.

4. The apparatus of claim 3, wherein the nitrogen-containing precursor is ammonia.

5. The apparatus of claim 4, wherein the silicon-containing precursor is BTBAS.

6. A method of processing a substrate, comprising:
introducing a substrate into a chamber;
introducing a nitrogen-containing precursor that does not include silicon into the chamber at a first flow rate;
introducing a boron-containing precursor into the chamber at a second flow rate, wherein the ratio of the first flow rate to the second flow rate is greater than or equal to about 10;
introducing a silicon-containing precursor into the chamber; and
reacting the nitrogen-containing precursor, the boron-containing precursor, and the silicon-containing precursor in the chamber to deposit a silicon boron nitride film on the substrate.

7. The method of claim 6, wherein the silicon boron nitride film is deposited at a substrate temperature between about 300° C. and about 600° C.

8. The method of claim 6, wherein the silicon boron nitride film has a dielectric constant between about 4.2 and about 5.7.

9. The method of claim 6, wherein the silicon boron nitride film is deposited at a deposition rate of at least about 100 Å/min.

10. The method of claim 6, wherein the boron-containing precursor is diborane.

11. The method of claim 10, wherein the nitrogen-containing precursor is ammonia.

12. The method of claim 6, wherein the silicon-containing precursor is BTBAS.

13. The method of claim 6, wherein the silicon boron nitride film further comprises carbon.

14. A method of processing a substrate, comprising:
introducing a substrate into a chamber;
introducing ammonia into the chamber at a first flow rate;
introducing diborane into the chamber at a second flow rate, wherein the ratio of the first flow rate to the second flow rate is greater than or equal to about 10;
introducing BTBAS into the chamber; and
reacting the ammonia, the diborane, and the BTBAS in the chamber to deposit a silicon boron nitride film on the substrate.

15. The method of claim 14, wherein the silicon boron nitride film is deposited at a substrate temperature between about 300° C. and about 600° C.

16. The method of claim 14, wherein the silicon boron nitride film is deposited at a substrate temperature between about 520° C. and about 550° C.

17. The method of claim 14, wherein the silicon boron nitride film has a dielectric constant between about 4.2 and about 5.7.

18. The method of claim 14, wherein the silicon boron nitride film is deposited at a deposition rate of at least about 100 Å/min.

19. The method of claim 14, wherein the silicon boron nitride film further comprises carbon.

20. The method of claim 14, wherein the diborane is introduced into the chamber from a first gas line system via a mixing block connected to the chamber, the ammonia is introduced into the chamber from a second gas line system via the mixing block, and the BTBAS is introduced into the chamber from a third gas line system via the mixing block.
